(19) United States
(12) Patent Application Publication
(10) Pub. No.: US 2011/0003256 A1
(43) Pub. Date: Jan. 6, 2011

(54) Lithographic Apparatus and Device Manufacturing Method

(75) Inventors: Robertus Wilhelmus VAN DER HEIJDEN, Tilburg (NL); Richard Johannes Franciscus Van Haren, Waalre (NL)

Correspondence Address: STERNE, KESSLER, GOLDSTEIN & FOX P.L.L.C., 1100 NEW YORK AVENUE, N.W., WASHINGTON, DC, 20005, US

(73) Assignee: ASML Netherlands B.V., Veldhoven (NL)

(21) Appl. No.: 12/822,416

(22) Filed: Jun. 24, 2010

Related U.S. Application Data
(60) Provisional application No. 61/223,132, filed on Jul. 6, 2009.

(51) Int. Cl. G03F 7/20; G03B 27/42

(52) U.S. Cl. 430/324; 430/322; 355/53

(57) ABSTRACT

A method for providing temporary measurement targets during a multiple patterning process which can be removed in the completion of the process. The metrology target is defined in either the first or the second exposure of a multiple exposure process and whether or not it is temporary or made permanent is selected according to whether or not the area of the target is covered or cleared out in the other exposure. The use of temporary targets reduces the amount of space on the substrate that must be devoted to targets.

### CROSS REFERENCE TO RELATED APPLICATIONS

This application claims benefit under 35 U.S.C. §119(e) to U.S. Provisional Patent Application No. 61/223,132, filed Jul. 6, 2009, which is incorporated by reference herein in its entirety.

### BACKGROUND

1. Field of the Invention

The present invention relates to a lithographic apparatus and a method for manufacturing a device.

2. Related Art

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In so-called double patterning processes, two pattern defining steps, e.g., lithographic exposures, are used to form each layer of the device. An example of such a process is litho-etch-litho-etch (LELE). In this method a first lithographic exposure and an etch step are used to pattern a hardmask with a first array of features, then a second lithographic exposure and a second etch are used to form a second array of features in the hardmask interleaved with the first array. Then the combined pattern is transferred into the device layer, e.g., by a further etch. The additional lithographic step increases both the strictness of overlay requirements and the number of measurements necessary to characterise overlay. In multiple pattering processes, it is necessary to measure inter-layer overlay between each of the two patterns making up layer n and each of the two patterns making up layer n+1 and also to measure intra-layer overlay. Spacer technology and extensions of double patterning to three or more patterns only increase the overlay measurement requirements. The need to measure additional overlay parameters necessitates the provision of additional overlay markers. However, the amount of space in scribe lanes for markers is limited and this space is also required for other purposes.

### SUMMARY

It is desirable to provide an improved method of measuring overlay in multiple-patterning processes.

According to an embodiment of the invention, there is provided a device manufacturing method comprising the following steps. A first exposure step wherein a first pattern is formed in a first resist layer. A second exposure step in which a second pattern is formed in a second resist layer A pattern transfer step in which the first and second patterns are transferred into a product layer. One of the first and second patterns includes features defining a metrology target; and the metrology target is not transferred into the product layer in the transfer step.

According to another embodiment of the present invention, there is provided a lithographic apparatus comprising a first support structure, a projection system, a substrate table, and a control system. The first support structure is configured to support a patterning device. The projection system is configured to project an image of the patterning device. The substrate table is configured to support a substrate in the projected image of the patterning device. The patterning device is configured to define a first pattern and a second pattern. The control system is adapted to control the lithographic apparatus to perform a first exposure step wherein a first pattern is formed in a first resist layer; a second exposure step in which a second pattern is formed in a second resist layer; a pattern transfer step in which the first and second patterns are transferred into a product layer; wherein one of the first and second patterns includes features defining a metrology target; and the metrology target is not transferred into the product layer in the transfer step.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 depicts a lithographic apparatus, according to an embodiment of the invention.

FIG. 2 depicts a lithographic cluster including a lithographic apparatus.

FIGS. 3 to 13 depict steps in a first method according to a first embodiment of the invention.

FIGS. 14 to 25 depict steps in a second method according to a second embodiment of the invention.

FIGS. 26 to 41 depict steps in a third method according to a third embodiment of the invention.

FIGS. 42 to 63 depict steps in a fourth method according to a fourth embodiment of the invention.

FIGS. 64 to 71 depict steps in a fifth method according to a fifth embodiment of the invention.

FIGS. 72 to 73 depicts a step in a variant of the fifth method according to a sixth embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

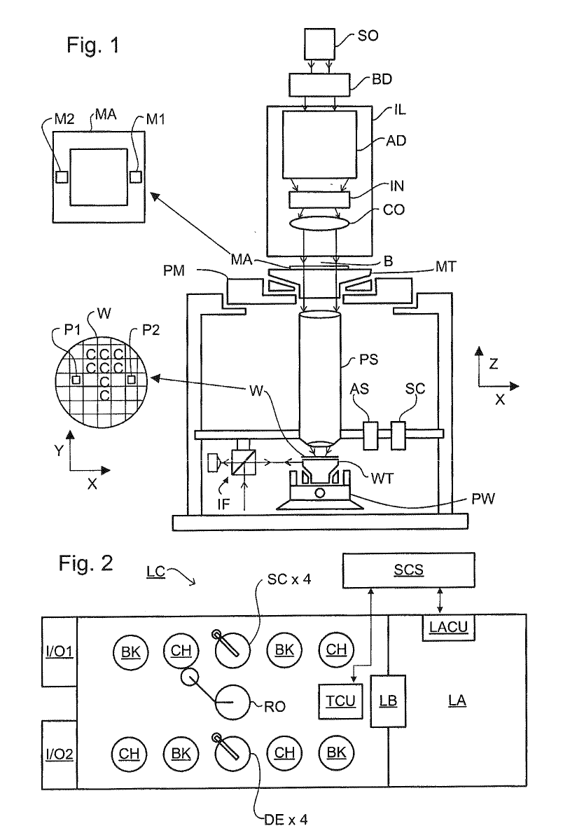

FIG. 1 schematically depicts a lithographic apparatus according to one embodiment of the invention. The apparatus comprises: an illumination system (illuminator) IL configured to condition a radiation beam B (e.g., UV radiation or DUV radiation); a support structure (e.g., a mask table) MT constructed to support a patterning device (e.g., a mask) MA and connected to a first positioner PM configured to accurately position the patterning device in accordance with certain parameters; a substrate table (e.g., a wafer table) WT constructed to hold a substrate (e.g., a resist coated wafer) W and connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

As shown in FIG. 2, the lithographic apparatus LA forms part of a lithographic cell LC, also sometimes referred to a lithocell or cluster, which also includes apparatus to perform pre- and post-exposure processes on a substrate. Conventionally these include spin coaters SC to deposit resist layers, developers DE to develop exposed resist, chill plates CH and bake plates BK. A substrate handler, or robot, RO picks up substrates from input/output ports I/O1, I/O2, moves them between the different process apparatus and delivers then to the loading bay LB of the lithographic apparatus. These devices, which are often collectively referred to as the track, are under the control of a track control unit TCU which is itself controlled by the supervisory control system SCS, which also controls the lithographic apparatus via lithography control unit LACU. Thus, the different apparatus can be operated to maximize throughput and processing efficiency.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. If errors are detected, adjustments may be made to exposures of subsequent substrates, especially if the inspection can be done soon and fast enough that other substrates of the same batch are still to be exposed. Also, already exposed substrates may be stripped and reworked—to improve yield—or discarded—thereby avoiding performing exposures on substrates that are known to be faulty. In a case where only some target portions of a substrate are faulty, further exposures can be performed only on those target portions which are good.

An inspection apparatus is used to determine the properties of the substrates, and in particular, how the properties of different substrates or different layers of the same substrate vary from layer to layer. The inspection apparatus may be integrated into the lithographic apparatus LA or the lithocell LC or may be a stand-alone device. To enable most rapid measurements, it is desirable that the inspection apparatus measure properties in the exposed resist layer immediately after the exposure. However, the latent image in the resist has a very low contrast—there is only a very small difference in refractive index between the parts of the resist which have been exposed to radiation and those which have not—and not all inspection apparatus have sufficient sensitivity to make useful measurements of the latent image. Therefore, measurements may be taken after the post-exposure bake step (PEB), which is customarily the first step carried out on exposed substrates and increases the contrast between exposed and unexposed parts of the resist. At this stage, the image in the resist may be referred to as semi-latent. It is also possible to make measurements of the developed resist image—at which point either the exposed or unexposed parts of the resist have been removed—or after a pattern transfer step such as etching. The latter possibility limits the possibilities for rework of faulty substrates, but may still provide useful information.

In order to meet the continual demand to be able to create devices with higher densities, various multiple (e.g., double) patterning and spacer processes have been proposed. The various multiple patterning processes, such as litho-etch-litho-etch (LELE) and litho-freeze-litho-etch (LFLE), differ in how one exposure is fixed whilst the next is made, but share the requirement that the positioning of the different exposure steps used to form one layer relative to each other and relative to other layers is critical. A single exposure process has a certain requirement for overlay between successive layers (inter-layer overlay), but multiple patterning processes have both stricter and more numerous inter-layer overlay requirements and introduce the need for intra-layer overlay requirements. Therefore, it is necessary to provide additional overlay targets per die when using a multiple patterning process.

Conventionally, overlay targets are provided in the scribe lanes, however space in the scribe lanes is limited and there are other uses for such space. It can therefore be difficult to accommodate the additional overlay targets required for multiple-patterning processes. Embodiments of the present invention provides a method whereby temporary measurement targets may be provided to assist in aligning exposures of a multiple patterning process and measuring intra-layer overlay. These temporary targets are removed in the completion of the process. They may therefore be provided within the product area as well as in the scribe lanes. Since there may be a significant height difference between the scribe lane and product areas after several product layers have been formed, providing the targets in the product area may provide an additional advantage in that it avoids errors and inaccuracy that may be caused by any height difference. Whether the target is in the product area or the scribe lane, the temporary nature of the targets means that target sites may be re-used in subsequent layers.

The targets formed by an embodiments of the invention may be of various types, e.g., alignment and overlay targets, etc., and may be intended for use with a variety of measurement devices, e.g., diffractive alignment sensors, overlay sensors, scatterometers, scanning electron microscopes, etc. The targets may be of any useful type, including gratings, chevrons, box-in-box, etc. The targets of an embodiment of the invention may be used for characterisation of layers that have or are being formed as well as alignment of the substrate prior to exposure. Characterization of layers may involve measurement of overlay as well as other parameters such as CD, CD uniformity, focus, dose, etc. either directly or via the use of target patterns that are particularly sensitive to such parameters. For example, target patterns that manifest a focus or dose error as an alignment offset may be used.

In an embodiment of the invention, a target is exposed onto and developed in a resist during a multiple patterning process. The developed pattern may then be temporarily fixed, for example by transferring it into a hardmask or “freezing” the developed resist. (NB although the term “freezing” is commonly used in describing some double-patterning techniques, it does not mean a pattern in developed resist is frozen by lowering its temperature. Rather the developed resist is chemically treated to render it insoluble in the solvent of the second resist.) Other targets, e.g., overly and CD metrology targets may be used in developed resist or even in some cases on undeveloped resist. Desired measurements, e.g., of overlay to previous layers or intra-layer overlay, can then be performed, or the target may be used for alignment of a next exposure. During a subsequent step, the target is stripped or else covered to prevent it transferring into a hardmask or the product layer. Covering the target can be achieved by not performing a clearout procedure on the target site. Of course, multiple targets may be formed in a given exposure step and some transferred into the product layer for use in subsequent measurements whilst others are not transferred and used only temporarily.

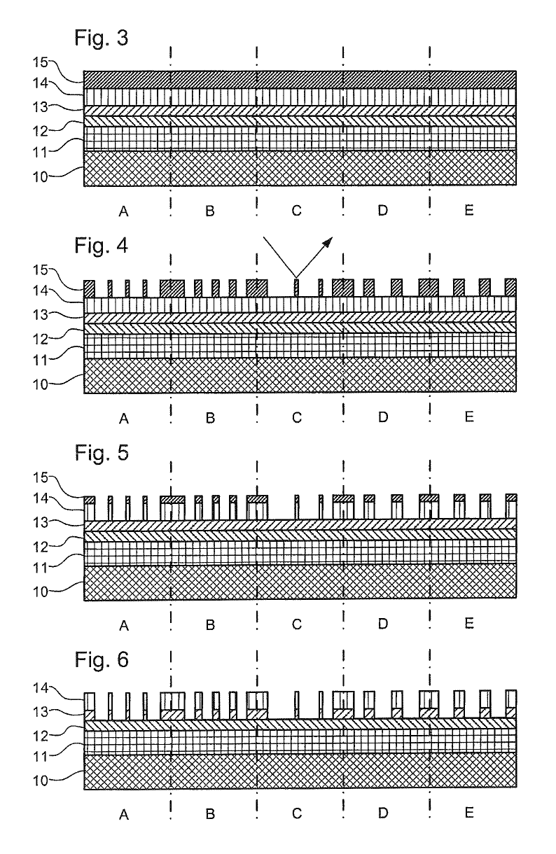

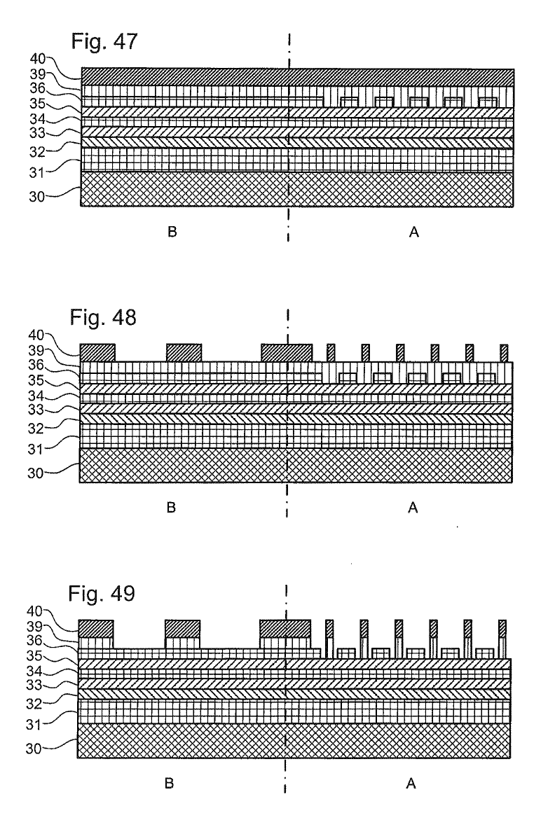

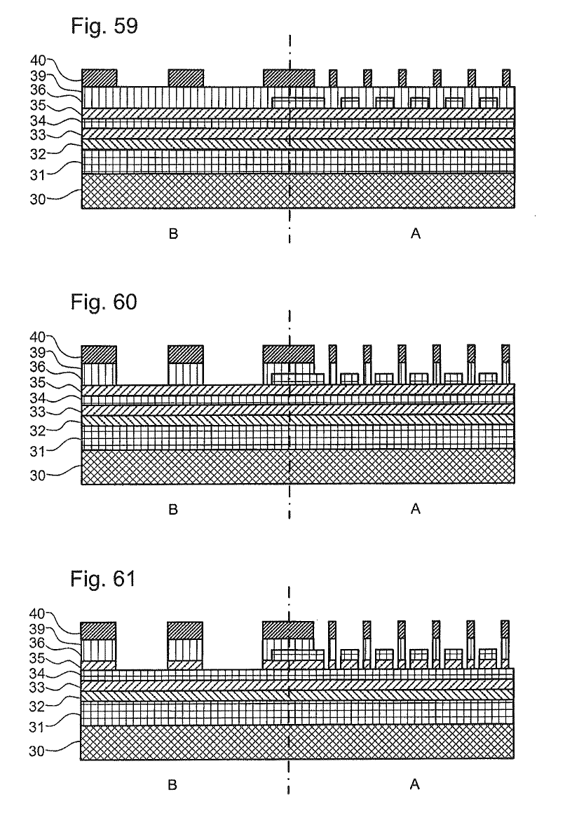

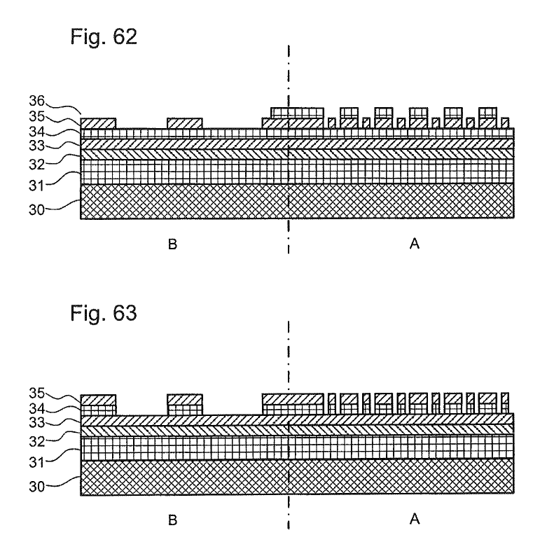

Some detailed embodiments of the method of the invention are described below with reference to FIGS. 3 to 62. Each of these Figures is a cross-section through a substrate and depicts the outcome of a step performed in an embodiment of the invention. These Figures are purely schematic, i.e., not to scale, and depict only part of a substrate being processed. The different hatching styles used in the drawings are simply to enable different layers to be distinguished between and do not indicate the use of particular materials. Example materials are given in the text below.

A first method according to an embodiment of the invention is described below with reference to FIGS. 3 to 13. This method is a dual-hardmask light-field (dual-line) double patterning process. FIG. 3 depicts the substrate at the beginning of the process. The underlying substrate 10 (e.g., of silicon) has a product layer 11 over which are provided a first hardmask 12, a second hard mask 13 (which may be omitted in some cases), a bottom anti-reflection coating (BARC) 14 and resist 15. Suitable materials to form the different layers in this and subsequent embodiments will be known to the person skilled in the art. The area of the substrate is notionally divided for the purpose of this description into regions depicted A to E. Region A is where the device is to be formed. Region B is for alignment markers. Regions C to E are for metrology, e.g., overlay. In particular region C is for inter-layer metrology relative to previously formed layers, region D is for inter-layer metrology relative to subsequent layers and region E is for intra-layer metrology.

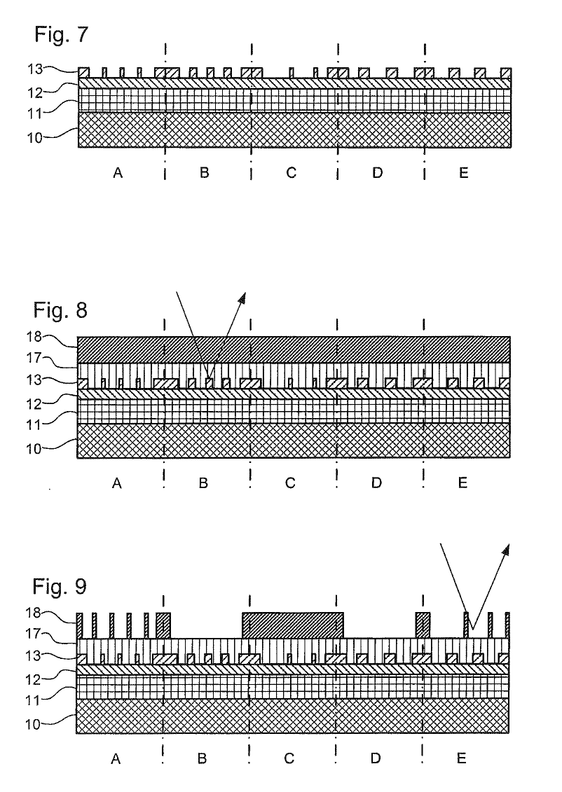

In the first lithography step, a first array of device (product) features as well as alignment and other targets are exposed onto the resist 15 which is then developed to removed unexposed areas (if a negative tone resist is used, exposed areas are removed if a positive tone resist is used), as shown in FIG. 4. At this stage measurements may be taken of the targets in region C, as indicated by the arrow, to perform inter-layer metrology (e.g., overlay measurement) to a previous layer. Then the BARC 14 is selectively etched to arrive at the state shown in FIG. 5. The image pattern is now defined in the developed resist and etched BARC so that a further selective etch transfers the pattern into a second hardmask 13. The remnants of the resist layer are removed during this process, as shown in FIG. 6. The BARC is then stripped to arrive at the position shown in FIG. 7 and then a second BARC 17 and second resist 18 are coated onto the substrate to reach the stage shown in FIG. 8. At this point, the alignment patterns formed in the second hardmask in region B can be used to align the substrate for the next exposure.

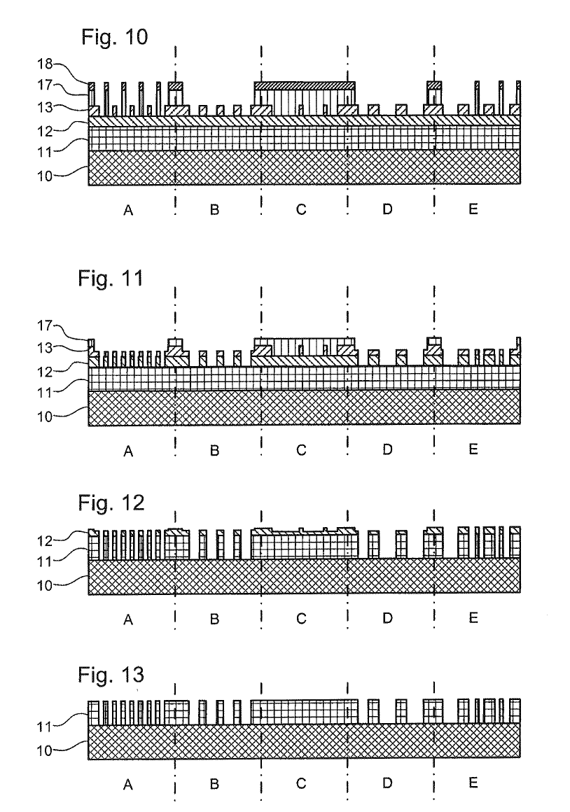

In the second lithographic exposure, a second array of product features, interspersed with the first array formed in the first exposure, are imaged in the product region A. Features are also formed in region E that combine with the features formed in the first lithographic and subsequent steps to form a marker useful for intra-layer metrology. The alignment region B and inter-layer metrology region D (for metrology relative to subsequent layers) are cleared out whilst inter-layer metrology region C (for metrology relative to previously formed layers) is left covered by resist. This is the stage depicted in FIG. 9, where these patterns are formed in developed resist 18. The intra-layer metrology measurements can now be taken of the combined pattern formed in region E. FIG. 10 shows the situation after the resist pattern is transferred into the second BARC 17 by a further etch.

In the next step, the combined pattern defined by the combination of the pattern formed in second hardmask 13 by the first exposure and formed in second BARC 17 by the second exposure are transferred by an etch into the first hardmask 12. This is depicted in FIG. 11. A further etch transfers the combined pattern formed in first hardmask into the product layer 11 as shown in FIG. 12 and the final step is to remove the remnants of first hardmask 12 to arrive at the situation shown in FIG. 13, with a patterned product layer 11 on a substrate 10.

It will be seen that because region C was left covered by resist after the second exposure, the pattern formed in second hardmask 13 was not transferred into the first hardmask 12 as shown in FIG. 11. Hence, the pattern does not transfer further into the product layer 11, as can be seen in FIG. 13. Thus, the temporary pattern formed in region C in the first exposure and used for inter-layer metrology relative to previously formed layers, is not present in the patterned device layer 11 so that this region may be re-used, e.g., for the formation of other markers, in subsequent exposures. The markers formed in regions B and D in the first exposure are transferred through to the patterned product layer 11 because those regions were cleared out in the second exposure. In region E, the patterned product layer 11 has a marker formed by a combination of features defined in both exposure steps.

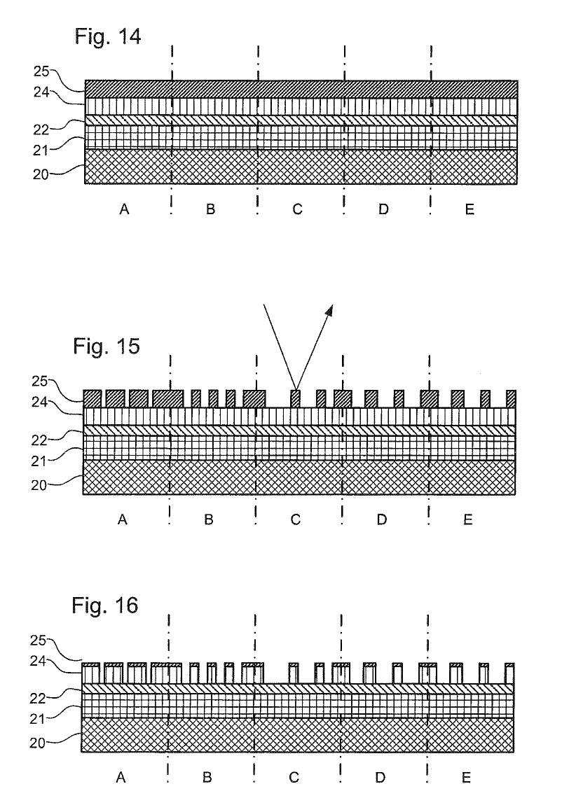

A second method according to an embodiment of the invention is described below with reference to FIGS. 14 to 25. This method is a single-hardmask dark-field (dual-trench) double patterning process. FIG. 14 depicts the substrate stack at the beginning of the process. On top of substrate (e.g., of silicon) 20 there are provided are target layer 21, a hardmask 22, a bottom anti-reflection coating (BARC) 24 and resist 25. As in the first embodiment, the substrate is notionally divided, for the purposes of this description, into regions A to E for, respectively, device features, alignment markers, inter-layer metrology relative to previously formed layers, inter-layer metrology relative to subsequent layers and intra-layer metrology.

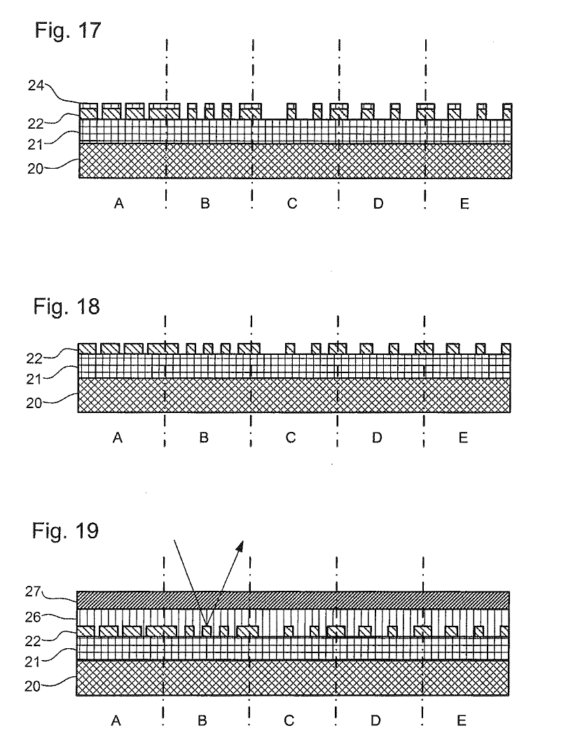

In the first lithography exposure, a first array of device (product) features as well as alignment and other targets are exposed onto resist 25 which is developed to remove unexposed areas, as shown in FIG. 15. At this stage, measurements may be taken of the targets in region C, as indicated by the area, to perform inter-layer metrology (e.g., overlay measurements) to a previous layer. A BARC etch is then performed to transfer the resist pattern into BARC 24 as shown in FIG. 16. After that, a hardmask etch is performed to transfer the pattern from the BARC to the hardmask 22, as shown in FIG. 17. Stripping the BARC layer leaves patterned hardmask 22 over target layer 21, as shown in FIG. 18.

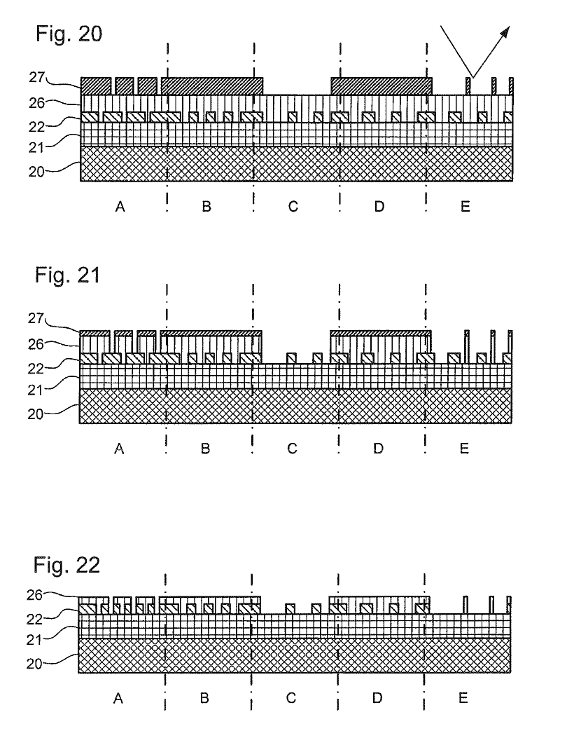

In preparation for the second exposure, a second BARC 26 and a second resist layer 27 are coated onto the substrate as shown in FIG. 19. The alignment patterns formed in region B in hardmask 22 can be used for aligning the substrate prior to the second lithographic exposure step. In the second exposure step, a second array of product features are defined in region A that will combine with the first array of features formed in the first lithographic step to define the ultimate pattern in the device layer 21 as shown in FIG. 20. Similarly, a second set of features is defined in region E so as to form a combined marker with the features formed in the first lithography step to enable the desired intra-layer metrology. The pattern formed in region E is such that most of region E is cleared of resist, leaving isolated resist features that are inter-leaved with the features formed in hardmask 22 without overlapping them. The intra-layer metrology (e.g., overlay between the first and second lithographic exposures) measurements can be performed now or after the next step, which is transfer of the resist pattern into second BARC 26, as shown in FIG. 21.

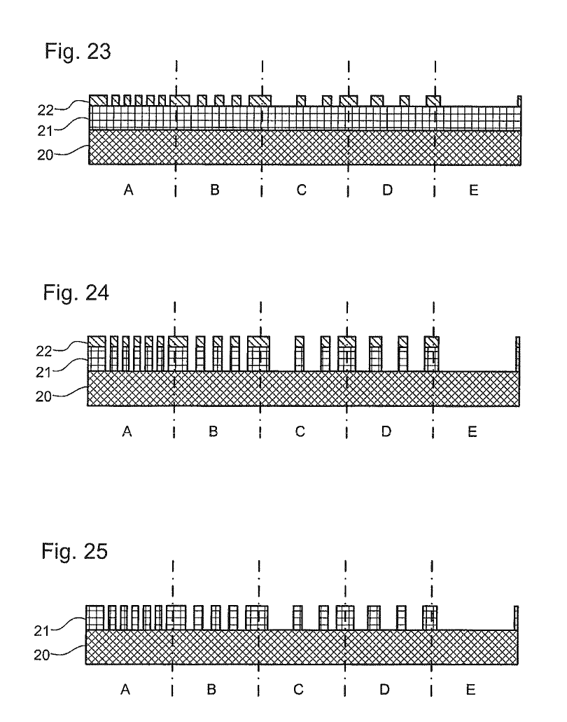

A second hardmask etch transfers the features formed in the second lithographic step into hardmask 22, which already contains the features defined in the first lithographic step as shown in FIG. 22. In region A the ultimately desired product features are now defined by the combination of the features formed in the first and second lithographic steps in regions B, C and D, no features were defined in the second lithographic step (the regions remained covered by resist) so that the hardmask 22 contains only the features formed in the first lithographic step. In region E, the areas of hardmask 22 left behind after transfer into the hardmask 22 of the pattern formed in the first lithographic step were not covered in the second lithographic exposure so that in this region now all traces of the hardmask 22 are removed. Stripping the second BARC 26 leaves the situation shown in FIG. 23: region A has features formed in both lithographic steps, regions B, C and D have features formed only in the first lithographic step and region E is clear of features. A pattern transfer step, such as a further etch, transfers this pattern into device layer 21 to arrive at the situation depicted in FIG. 24 then stripping of the remnants of hardmask 22 provides the final product, depicted in FIG. 25.

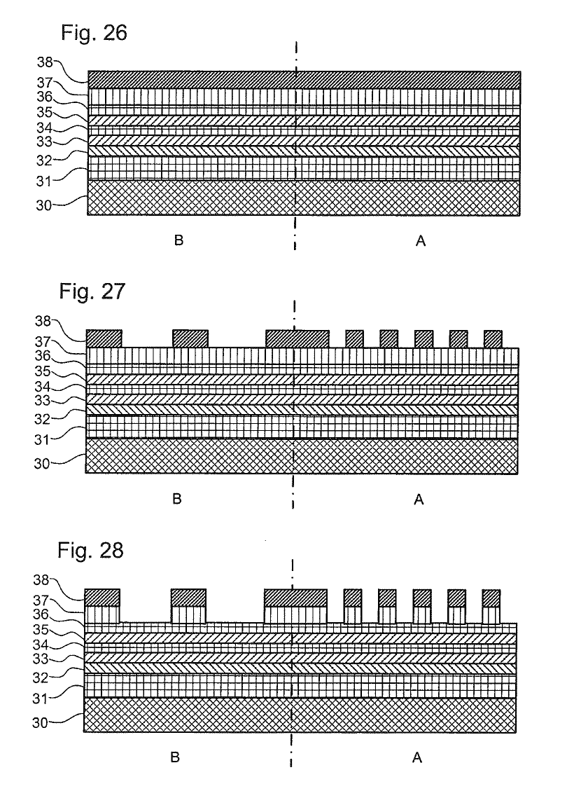

A third method according to an embodiment of the invention is described below with reference to FIGS. 26 to 41. This method is a dual-hardmask light-field (dual-line) double patterning process. FIG. 26 depicts the substrate at the beginning of the process. The underlying substrate 30 (e.g., of silicon) is covered by a gate layer or stack 31 (e.g., of polysilicon). This in turn is covered by a hardmask 32 (e.g., of α-C). Above this is the double patterning imaging stack comprising, upwards from the bottom, a first SiON layer 33, a first polysilicon layer 34, a second SiON layer 35, a second polysilicon layer 36, a BARC layer 37 and a resist layer 38. For the purposes of this description, this substrate is notionally divided into a product region A and a target region B. This imaging stack is described in the article “Alternative Technology for Double Patterning Process Simplification” by Hee-Youl Lim et al, Lithography Asia 2008Proc. Of SPOE Vol. 7140, 714020, which document is hereby incorporated by reference herein in its entirety.

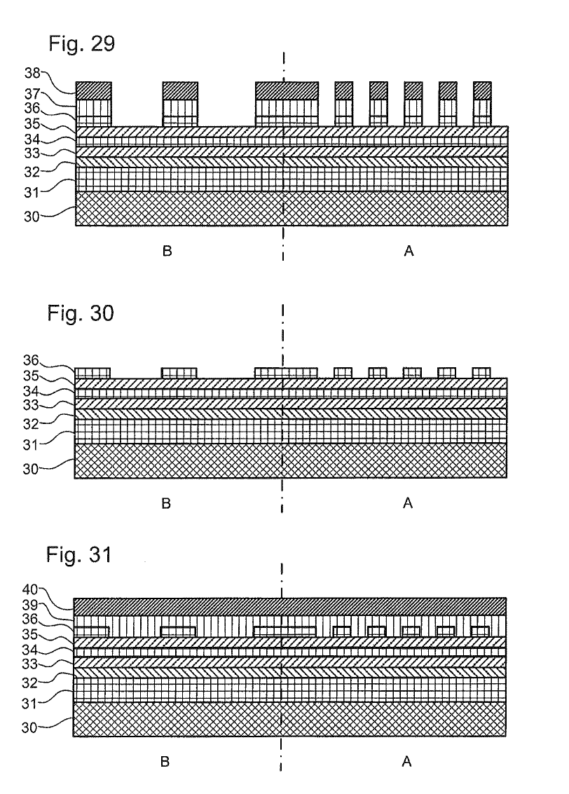

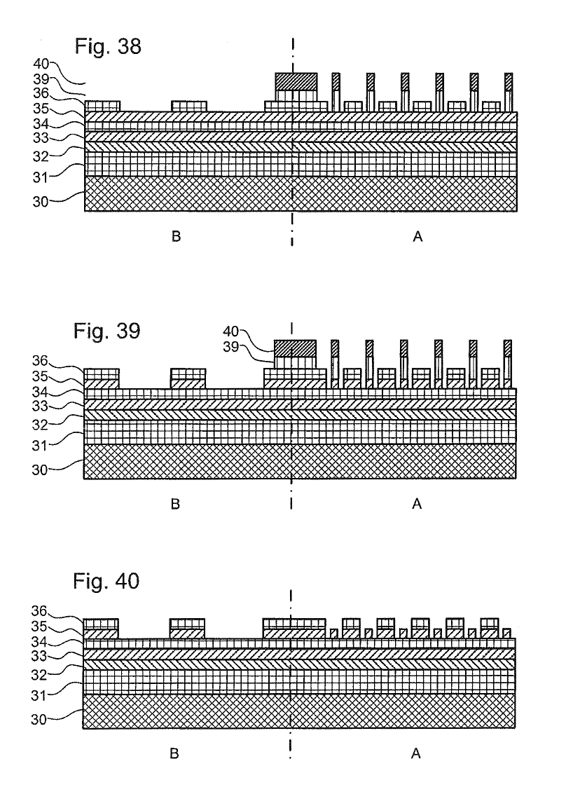

The first step is to expose the substrate to define in area A a first array of product (device) features and in area B a target, e.g., an alignment mark. After development of the resist 38, the situation depicted in FIG. 27 is reached. A BARC etch transfers the resist pattern in the BARC layer 37 as depicted in FIG. 38. A polysilicon etch transfers that pattern into the second polysilicon layer 36 as depicted in FIG. 29. Then, the photo resist and BARC are removed to arrive at the situation depicted in FIG. 30.

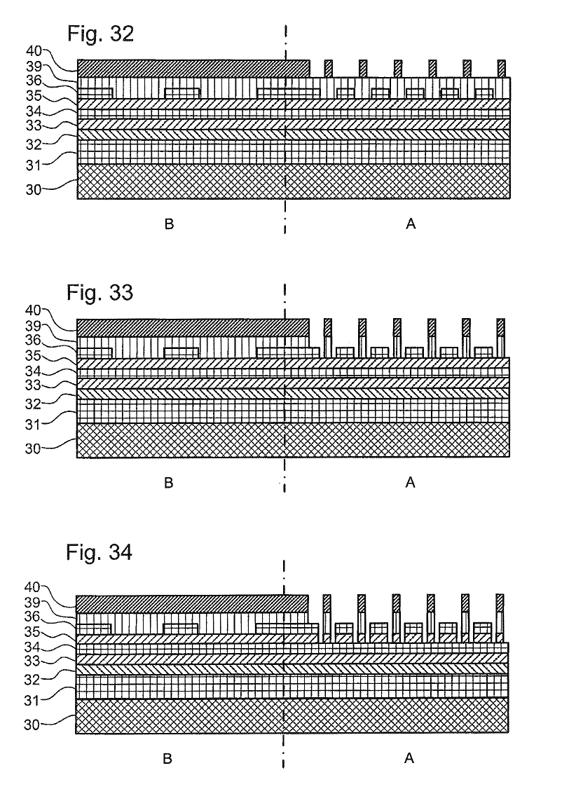

Thereafter, in preparation for the second imaging step, a second BARC layer 39 and a second photo resist layer 40 are coated onto the substrate. The target, e.g., alignment mark, in region B may at this point be used for metrology, e.g., alignment, prior to the second exposure. In the second exposure, a second array of product (device) features is defined in product region A inter-leaved with the features defined in the first exposure and subsequently transferred into the second hardmask 36. The target region B remains covered by photo resist, as shown in FIG. 32.

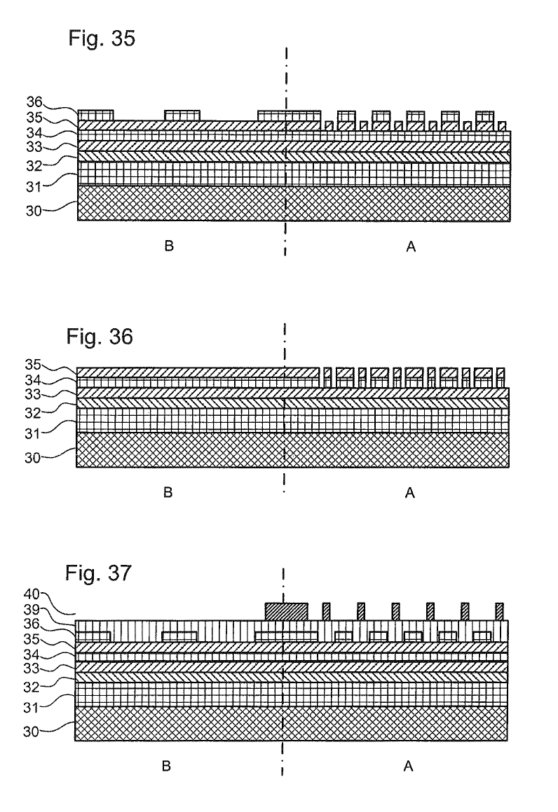

The pattern defined in resist is then transferred into the second BARC layer 39 by a BARC etch to arrive at the position shown in FIG. 33. An etch selective to SiON then transfers the combined pattern formed by the features of the first and second exposures into second SiON layer 35. This is shown in FIG. 4. Removal of the remnants of the second resist 40 and second BARC layer 39 produces the situation shown in FIG. 35. At this stage, the alignment mark is still defined in the second polysilicon layer 36, which also manifests the product features of the second exposure. The combined product features from both the first and second exposures are defined in second SiON layer 35. A polysilicon etch then removes second polysilicon layer 36 and transfers the combined pattern of product features into first polysilicon layer 34. This gets us to the situation shown in FIG. 36, where it can be seen that the target is completely removed. Any further processes that may be desirable to transfer the device pattern into hard mask 32 and/or underlying product stack 31, will not transfer the target. Region B can therefore be reused in subsequent layers.

FIGS. 37 to 41 correspond to FIGS. 32 to 36 and show that by clearing out the target in the second exposure step, the target is transferred into first polysilicon layer 34 and then into any other layers if further pattern transfer steps are performed. Thus, the present invention enables targets defined in a first exposure of a double patterning process to be selectively made temporary or permanent according to whether or not those areas are cleared out in the second exposure step.

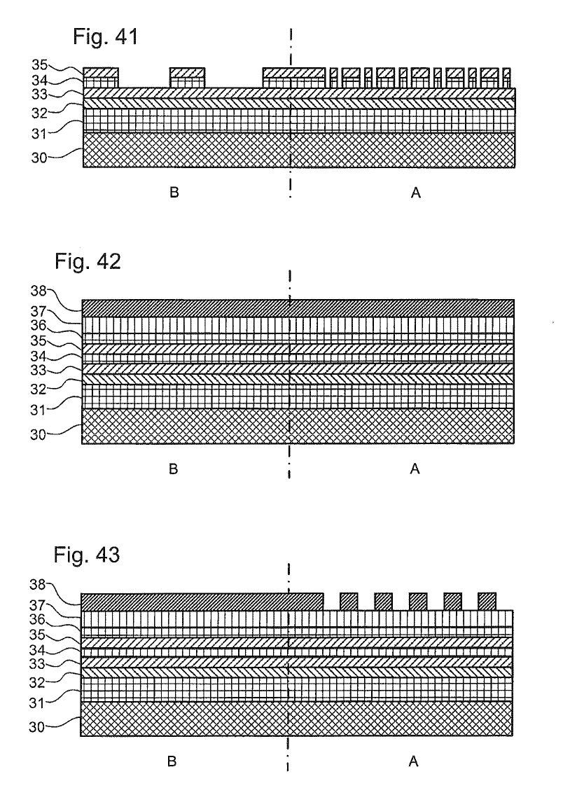

A fourth method according to an embodiment of the invention is described below with reference to FIGS. 42 to 63. This method is a variant of the third method in which the target is defined in the second exposure step rather than the first. FIG. 42 depicts the substrate of the beginning of the process, this is the same as the initial substrate depicted in FIG. 6. In other words, the underlying substrate 30 (e.g., of silicon) is covered by a gate layer or stack 31 (e.g., a polysilicon). This in turn is covered by a hard mask 32 (e.g., of α-C) above which is the double patterning imaging stack comprising, upwards from the bottom, a first SiON layer 33, a first polysilicon layer 34, a second SiON layer 35, a second polysilicon layer 36, a BARC layer 37 and a resist layer 38. Again, for the purposes of this description, this substrate is notionally divided into a product area A and a target area B.

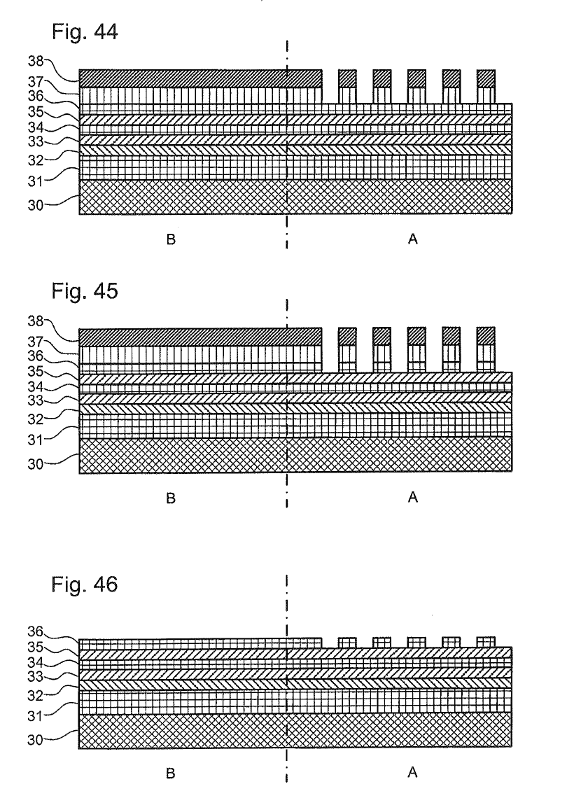

The fourth method proceeds along the same steps as the third method but in the first exposure, whilst the first array of product features is defined in product region A, the target region B is left covered with resist, as shown in FIG. 43. A BARC etch (FIG. 44), polysilicon etch (FIG. 45) and photo resist and BARC removal in turn produce a situation shown in FIG. 46: the first array of product features is defined in second polysilicon layer 36 in product region A but second polysilicon layer 36 remains unpatterned in target region B.

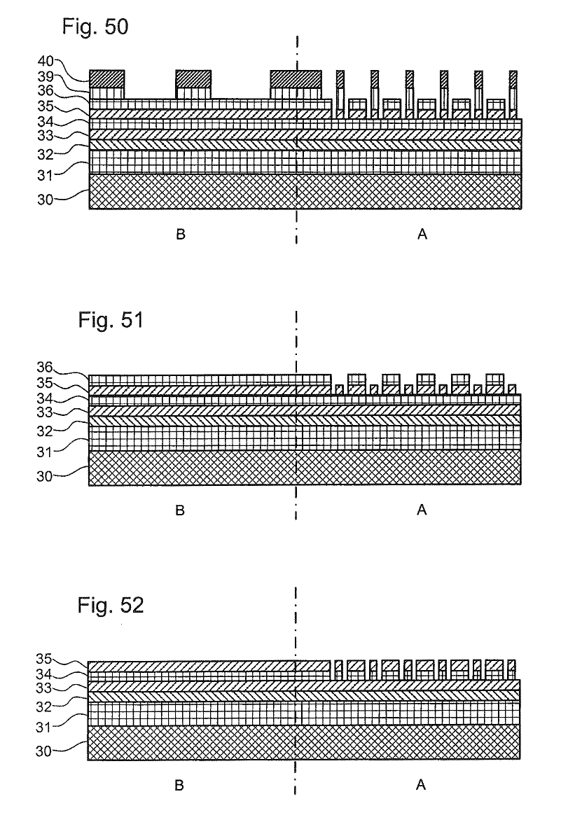

For the second exposure step, a substrate is coated again with a second BARC layer 39 and second resist 40. In the second imaging step, the second resist 40 is patterned in product region A with the second array of product features and in the target region B with a target, e.g., an alignment mark. FIG. 48 shows this after development of the resist. A BARC etch (FIG. 49) and an SiON etch (FIG. 50) transfers the second array of product features into the second BARC layer 39 and then the second SiON layer 35. However, the target, although transferred into the second BARC layer 39 by the BARC etch, is prevented from being transferred into the second SiON layer 35 by the second polysilicon layer 36 which remains intact in target region B. Photo resistant and BARC removal (FIG. 51) and a polysilicon etch produce the situation depicted in FIG. 52 where the combined product features from the first and second exposures are defined in first polysilicon layer 34 and second SiON layer 35 but no trace of the target defined in the second exposure remains.

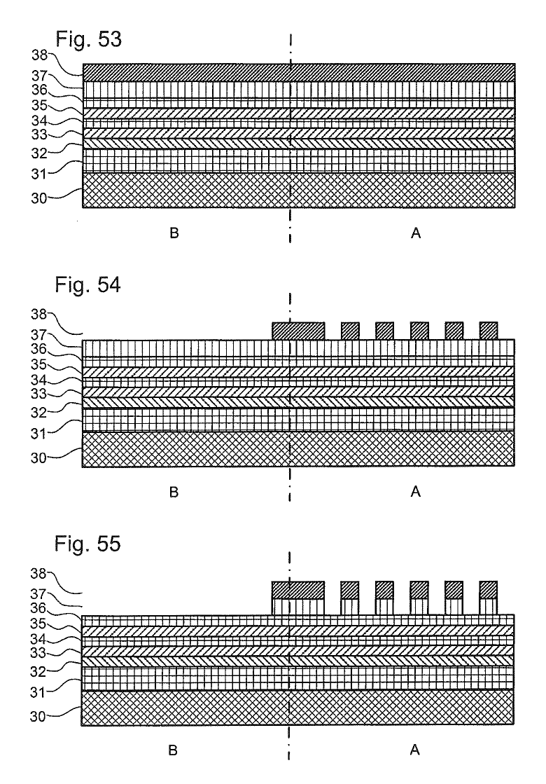

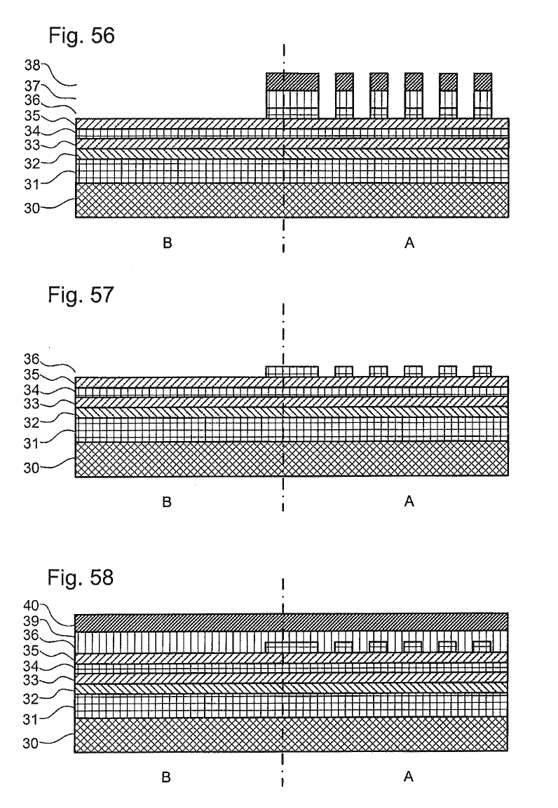

FIGS. 53 to 63 correspond to FIGS. 42 to 52 but show what happens if target region B is cleared out in the first exposure step, as shown in FIG. 54. It can then be seen that the second polysilicon layer 36 is removed in target region B by the polysilicon etch (FIG. 56). Therefore, in the SiON etch after the second exposure, the target defined in target region B is transferred into second SiON layer 35 and ultimately into first polysilicon layer 34.

Thus, whether or not a target pattern in a second imaging step of a double patterning process is temporary or permanent can be controlled according to whether or not the area in which the target is to be formed is cleared out or not in the first imaging step. An overlay target defined in the second imaging step allows intralayer overlay over interlay overlay to subsequent layers to be measured. An alignment target defined in the second imaging step allows alignment to that pattern.

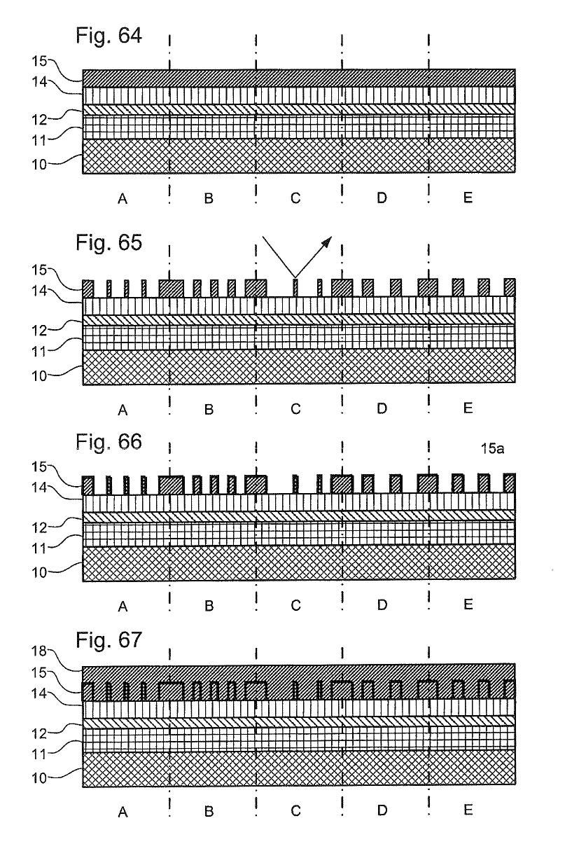

A fifth method according to an embodiment of the invention is described below with reference to FIGS. 64 to 72.

This method is a litho-freeze-litho-etch (LFLE) single hardmask dual line (bright field) double patterning process. FIG. 64 depicts the substrate at the beginning of the process. Reference numerals used in the description of this method indicates corresponding items to those of the first method. Thus, the substrate at the beginning of the process comprises an underlying substrate 10, a product layer 11, a hardmask 12, a bottom anti-reflection coating (BARC) 14 and resist 15. Again, suitable materials to form the different layers will be known to the person skilled in the art. The area of the substrate is again notionally divided for the purpose of the description into regions A-E. Region A is where the device (product) is to be formed. Region B is for alignment markers. Regions C-E are for metrology, e.g., overlay. In particular region C is for inter-layer metrology relative to previously formed layers, region D is for inter-layer metrology relative to subsequent layers and region E is for intra-layer metrology.

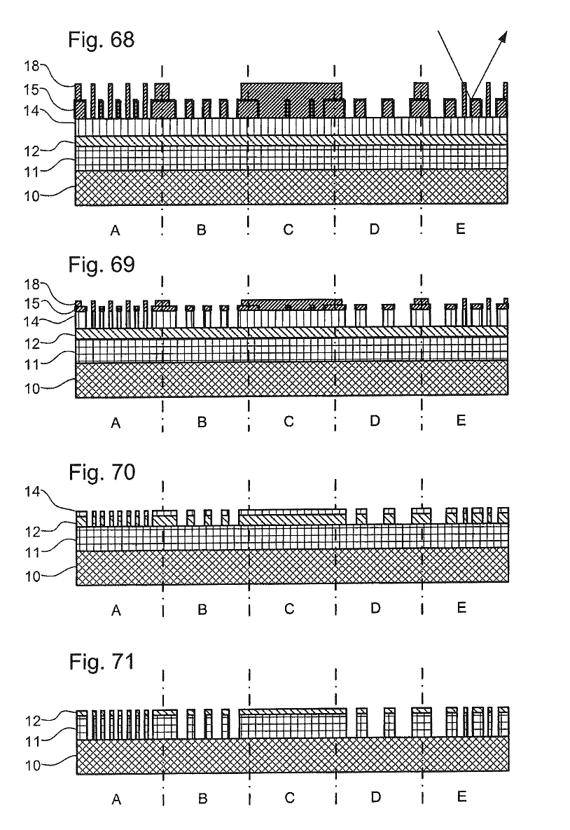

In the first lithography step a first array of device features as well as alignment and other targets are exposed onto resist 15 which is then developed to remove undesired areas, as shown in FIG. 65. At this stage measurements may be taken of the targets in region C as indicated by the arrow. To perform inter-layer metrology (e.g., overlay measurements) to a previous layer. Then, the pattern resist 15 is “frozen”. The resist 15 may be frozen by various methods to form an outer coating 15a which is relatively insoluble to the bottom anti-reflection coating or resist to be deposited on top of the frozen resist. For example, a separate coating layer may be applied for the develop resist covered temporarily with a reagent which reacts with the developed resist to perform a relatively insoluble outer layer. This is depicted in FIG. 66. Next, a second resist 18 is deposited on top of the developed and frozen resist 15, as shown in FIG. 67. This second resist is exposed to the second pattern as shown in FIG. 68.

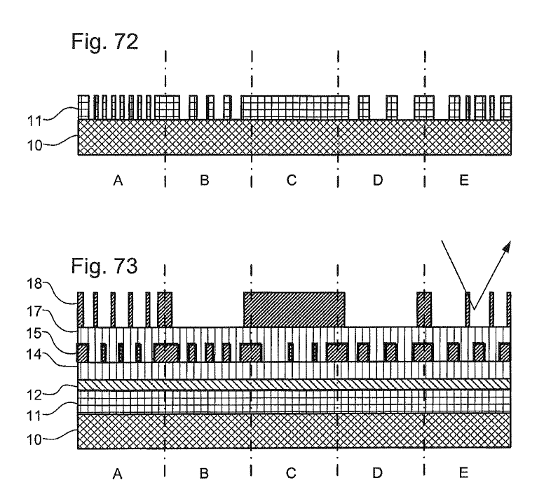

In region A, a second array of product features, interspersed with the first array formed in the first exposure, are formed. Features are also formed in region E that combined with the features formed in the first exposure to form a marker useful for intra-layer metrology. The alignment region B and interlayer metrology region D (for metrology relative to subsequent layers) are cleared out whilst interlayer metrology region C (for metrology relative to previously formed layers) is left covered by the resist. This is the situation depicted in FIG. 68. The intra-layer metrology measurements can now be taken of the combined pattern formed in region E. FIG. 69 shows the result of transferring the resist pattern into the BARC 14 by a further etch. Next, a combined pattern formed by the combination of the patterns from the first and second exposures formed in BARC 14 is transferred into hardmask 12 (FIG. 70) and then into product layer 11 (FIG. 71). Finally the remnants of hardmask 12 are stripped to reach the situation shown in FIG. 72.

It will be seen that because region C was left covered by resist after the second exposure, the pattern formed in first resist 15 in this region was not transferred into the hardmask 12. Hence, the pattern does not transfer into the product layer 11, as can be seen in FIG. 72. Thus, the temporary pattern formed in region C in the first exposure and used for inter-layer metrology relative to previously formed layers, is not present in the patterning device layer 11 so that this region may be reused, e.g., for the formation of other markers, in subsequent exposures. The markers formed in regions B and D in the first exposure are transferred through to the patterned product layer 11 because those regions were cleared out in the second exposure. In region E, the patterned product layer has a marker formed by a combination of features defined in both exposure steps.

A variant on this method is to deposit a second BARC layer 17 on top of the frozen layer 15. This is shown in FIG. 73, which also shows the patterned second resist 18 on top of the second BARC 17. This variant introduces the additional step of depositing the second BARC 17 and also an additional BARC etch. However, it may be useful if there is insufficient optical contrast between the second resist and the frozen first resist for reliable alignment to the alignment pattern formed in the first exposure.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that an embodiment of the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

### CONCLUSION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A device manufacturing method comprising:
a first exposure that forms a first pattern in a first resist layer;
a second exposure that forms a second pattern in a second resist layer; and
pattern transferring the first and second patterns into a product layer,
wherein one of the first and second patterns includes features defining a metrology target, and
wherein the metrology target is not transferred into the product layer in the transfer.

2. The method of claim 1, further comprising:
a second pattern transfer in which the pattern formed in the first exposure is transferred into a first hardmask prior to the second exposure;
a third pattern transfer step in which the second pattern formed in the second resist is transferred to a second hardmask prior to the pattern transfer and wherein the pattern transfer transfers the first and second patterns formed in the first and second hardmasks into the product layer.

3. The method of claim 2, wherein:
the metrology target is defined in a first area of the first pattern; and
the second pattern is such that a second area thereof corresponding to the first area of the first pattern remains covered in the second transfer step.

4. The method of claim 2, wherein the metrology target is defined in a first area of the second pattern and the first pattern is such that a second area thereof corresponding to the first area of the second pattern remains open during the first transfer step.

5. The method of claim 1, further comprising:
a second pattern transfer step in which the pattern formed in the first exposure step is transferred into a hardmask prior to the second exposure step; and
a third pattern transfer step in which the second pattern formed in the second resist is transferred to the hardmask prior to the pattern transfer step.

6. The method of claim 5, wherein the metrology target is formed in a first area of the first pattern and the second pattern is such as to form a continuous resist layer in a second area of the second pattern corresponding to the first area of the first pattern.

7. The method of claim 5, wherein:
the metrology target comprises a combination of features defined in the first pattern and features defined in the second pattern; and
the features of the metrology target defined in the first pattern and the features of the metrology target defined in the second pattern do not overlap with each other.

8. The method of claim 1, further comprising:
fixing the first pattern in the first resist layer and applying the second resist layer before the second exposure; and
a second pattern transfer in which the first pattern fixed in the first resist and the second pattern formed in the second resist are transferred into a hardmask;
wherein the pattern transfer transfers the first and second patterns from the hardmask into the product layer.

9. The method of claim 8, wherein:
fixing the first pattern comprises reacting the exposed first resist with a reagent so as to reduce the solubility of the exposed first resist in the second resist.

10. The method of claim 8, wherein:
fixing the first pattern comprises coating the exposed first resist with a material that is insoluble in the second resist.

11. The method of claim 8, further comprising applying a bottom anti-reflection coating after fixing the first pattern and before applying the second resist.

12. The method of claim 8, wherein the metrology target comprises gratings, chevrons, or box-in-box targets.

13. The method of claim 8, comprising the further step of measuring a characteristic of the substrate prior to the third transfer.

14. The method of claim 3, wherein the characteristic of the substrate is a characteristic comprising critical dimension, critical dimension uniformity, focus, dose, overlay of the first pattern relative to the second pattern, overlay of the first pattern relative to a pattern previously formed on the substrate, or overlay of the second pattern relative to a pattern previously formed on the substrate.

15. The method of claim 1, wherein the metrology target is formed within a scribe lane of the substrate.

16. The method of claim 1, wherein the metrology target is defined within a product area of the substrate.

17. A lithographic apparatus comprising:
a first support structure configured to support a patterning device configured to define a first pattern and a second pattern;
a projection system configured to project an image of the patterning device;
a substrate table configured to support a substrate in the projected image of the patterning device; and
a control system adapted to perform a method comprising:
a first exposure that forms a first pattern in a first resist layer;
a second exposure that forms a second pattern in a second resist layer; and
pattern transferring the first and second patterns into a product layer,
wherein one of the first and second patterns includes features defining a metrology target, and
wherein the metrology target is not transferred into the product layer in the transfer.
